(19) United States
(12) Patent Application Publication
(10) Pub. No.: US 2006/0134875 A1
(43) Pub. Date: Jun. 22, 2006

(54) Method of forming storage node of capacitor

(75) Inventors: Tae-Hyuk Ahn, Yongin-si (KR); Jung-Woo Seo, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/284,389

(22) Filed: Nov. 21, 2005

(30) Foreign Application Priority Data
Dec. 17, 2004 (KR) 10-2004-0108007

(51) Int. Cl. H01L 21/20

(52) U.S. Cl. 438/381

(57) ABSTRACT

A method of forming a storage node of a capacitor includes defining a cell region and a peripheral circuit region in a semiconductor substrate. An interlayer insulating layer is formed on the semiconductor substrate of the cell region and the peripheral circuit region. Buried contact plugs are formed to penetrate the interlayer insulating layer of the cell region. A molding layer is formed on the semiconductor substrate of the cell region and the peripheral circuit region. The molding layer of the cell region is patterned, thereby forming storage node holes exposing the buried contact plugs. A conformal storage node layer is formed on the semiconductor substrate having the storage node holes. A photosensitive layer is formed on the semiconductor substrate having the storage node layer. At this time, the photosensitive layer in the cell region is lower in height than the photosensitive layer in the peripheral circuit region. The semiconductor substrate is exposed using a reticle having a scattering bar. The scattering bar of the reticle is positioned to correspond with the cell region. An exposed portion of the photosensitive layer is removed by developing the semiconductor substrate, thereby partially exposing the storage node layer. The photosensitive layer in the storage node holes is therefore maintained. An etch-back is performed on the semiconductor substrate having the exposed storage node layer, thereby separating storage nodes.

### CROSS-REFERENCE TO RELATED APPLICATION

This application claims priority from Korean Patent Application No. 10-2004-108007, filed on Dec. 17, 2004, the disclosure of which is hereby incorporated herein by reference in its entirety as if set forth fully herein.

### BACKGROUND OF INVENTION

1. Technical Field

The present invention relates to a semiconductor device fabrication and more particularly, to a method of forming a storage node of a capacitor.

2. Discussion of the Related Art

In a semiconductor memory device, for example, dynamic random access is memory (DRAM), data are stored in a capacitor of each unit cell. That is, the unit cell of the DRAM is composed of one access transistor and one cell capacitor, which are connected in series. However, as the degree of integration of DRAM devices continues to increase, the available area of such a unit cell is rapidly reduced, and the capacitance of the capacitor is also decreased. The capacitance of the capacitor refers to its capacity to store data, and if the capacitance is low, there occurs a malfunction in which data which was stored is wrongly read out. Thus, the capacitance of the capacitor must be maintained in order to realize a high performance DRAM.

In view of the capacitance formula of a capacitor Cc=εA/d (ε: permittivity, A: surface area, d: thickness of dielectrics), methods of increasing a capacitance Cc of a cell capacitor within a limited cell area may include reducing a thickness d of the capacitor dielectric, increasing the effective surface area A, and using a material having a high permittivity ε.

In the conventional method of increasing capacitance, a material having a high permittivity ε, for example, a dielectric layer such as Ta₂O₅ or BST ((Ba, Sr)TiO₃), is used as a dielectric layer. However, in the case of using the dielectric layer, a polysilicon layer normally used as an electrode is difficult to use as a capacitor electrode. This is because a reduced thickness of a dielectric layer causes a leakage current due to tunneling. Thus, in the case of using a high-k dielectric layer or a ferroelectric layer as a dielectric layer, a valuable metal material such as platinum (Pt), ruthenium (Ru), iridium (Ir), rhodium (Rh), osmium (Os), and the like having a very high work function, or a conductive compound such as TiN and the like are used as a capacitor electrode material.

In the conventional technology, a sacrificial layer is formed with a sufficient thickness to completely fill a storage node hole in order to separate a storage node of a cell capacitor, and the sacrificial layer is partially removed using CMP or etch-back so that a storage node layer is separated into a plurality of storage nodes. However, in the case that a storage node layer is normally formed of polysilicon, a CMP process is used to separate storage nodes via planarization, but in the case of metal, fabrication cost is increased to employ metal CMP equipment and it is necessary to develop slurry. Further, use of new equipment may introduce problems with existing processes. Initial costs and time can be saved by an etch-back process.

FIGS. 1A to 1D are sectional views illustrating a method of forming a storage node of a capacitor by a conventional etch-back process.

Referring to FIG. 1A, a cell region C and a peripheral circuit region P are defined in a semiconductor substrate 10. An interlayer insulating layer 15 is formed on the semiconductor substrate 10. The interlayer insulating layer 15 is formed of an oxide layer. Before the interlayer insulating layer 15 is formed, even though not shown on the semiconductor substrate 10 in the drawing, process-completed transistors and a bit line are formed. The interlayer insulating layer 15 is patterned, thereby forming buried contact holes exposing predetermined regions of the semiconductor substrate 10. Buried contact plugs 20 are formed in the buried contact holes. An etch stop layer 25 and a molding layer 30 are sequentially formed on the semiconductor substrate having the buried contact plugs 20. The etch stop layer 25 is formed of a silicon nitride layer. The molding layer 30 is formed of an oxide layer. The molding layer 30 and the etch stop layer 25 are sequentially patterned, thereby forming storage node holes 35 exposing the buried contact plugs 20.

Referring to FIG. 1B, a conformal storage node layer 40 is formed on the semiconductor substrate having the storage node holes 35. The storage node layer 40 is composed of TiN.

A photosensitive layer 45 is formed on the semiconductor substrate having the storage node layer 40 to fully fill the storage node holes 35. At this time, as the photosensitive layer comes into the storage node holes 35 in the cell region C having the storage node holes 35, a height of the photosensitive layer is lowered to a level lower than that in the peripheral circuit region P, thereby to cause a step height difference in the structure.

The semiconductor substrate having the photosensitive layer 45 is exposed using a blank reticle BR or without a reticle. At this time, an exposure energy is applied under a condition that the photosensitive layer 45 of the peripheral circuit region P is entirely removed following development.

Referring to FIG. 1C, the exposed semiconductor substrate is developed. As a result, the photosensitive layer 45 of the peripheral circuit region P is entirely removed. In the cell region C, an upper photosensitive layer 45 is removed, and the photosensitive layer 45 in the storage node hole 35 is partially recessed, thereby forming a recessed photosensitive layer 45a, in which an upper portion R of the storage node hole 35 is exposed.

Referring to FIG. 1D, an etch-back process is performed on the developed semiconductor substrate in order to separate storage nodes. As a result, the exposed portions of the storage node layer 40 are etched, thereby forming storage nodes 40a having upper nodes that are separated. At this time, the storage node layer 40 in the upper portion R of the storage node hole 35, which is not filled with the recessed photosensitive layer 45a, is removed by the etch-back process. As a result, a height of the storage nodes 40a is relatively lowered in comparison with a height of the molding layer 30. Thus, the area of the capacitor is reduced, and the capacitance of the capacitor is reduced.

As described above, during node separation of the storage nodes of a capacitor, since a thickness of the deposited photosensitive layer is different between the cell region C and the peripheral circuit region P, an upper portion of the storage node is excessively etched during a subsequent etch-back of the storage node layer, which results in a reduction of the capacitance of the resulting capacitor.

### SUMMARY OF THE INVENTION

Therefore, the present invention is directed to a method of forming a storage node of a capacitor for sufficiently ensuring the resulting heights of storage nodes by reducing loss of a photosensitive layer within the storage nodes holes during deposition of a photosensitive layer, and exposure and development of the photosensitive layer in a process of separating storage nodes.

In one aspect, the present invention provides a method of forming a storage node of a capacitor. The method includes defining a cell region and a peripheral circuit region in a semiconductor substrate. An interlayer insulating layer is formed on the semiconductor substrate of the cell region and the peripheral circuit region. Buried is contact plugs are formed to penetrate the interlayer insulating layer of the cell region. A molding layer is formed on the semiconductor substrate of the cell region arid the peripheral circuit region. The molding layer of the cell region is patterned, thereby forming storage node holes exposing the buried contact plugs. A conformal storage node layer is formed on the semiconductor substrate having the storage node holes. A photosensitive layer is formed on the semiconductor substrate having the storage node layer. At this time, the photosensitive layer in the cell region is lower in height than the photosensitive layer in the peripheral circuit region. The semiconductor substrate is exposed using a reticle having a scattering bar. The scattering bar of the reticle is positioned to correspond with the cell region. An exposed portion of the photosensitive layer is removed by developing the semiconductor substrate, thereby partially exposing the storage node layer. The photosensitive layer in the storage node holes is maintained. An etch-back is performed on the semiconductor substrate having the exposed storage node layer, thereby separating storage nodes.

In one embodiment, an etch stop layer is further formed between the interlayer insulating layer and the molding layer.

In another embodiment, the storage node layer is formed of a metal layer or conductive compound. In another embodiment, the storage node layer is a TiN layer.

In another embodiment, the photosensitive layer is formed to fully fill the storage node hole.

In another embodiment, in exposing the semiconductor substrate, the exposure energy passing through the scattering bar of the reticle is reduced and thus, an exposure energy of the cell region corresponding to the scattering bar is reduced.

In another embodiment, the scattering bar is composed of a line and space pattern or an island pattern, or combination thereof.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1A to 1D are sectional views illustrating a method of forming a storage node of a capacitor by a conventional etch-back process;

FIGS. 2A to 2D are sectional views illustrating a method of forming a storage node of a capacitor according to an embodiment of the present invention; and

FIG. 3 is a graph illustrating comparison of exposure energy of a peripheral circuit region and a cell region according to a conventional approach and according to an embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. In the drawings, the thicknesses of layers and regions are exaggerated for clarity. Like numbers refer to like elements throughout the specification.

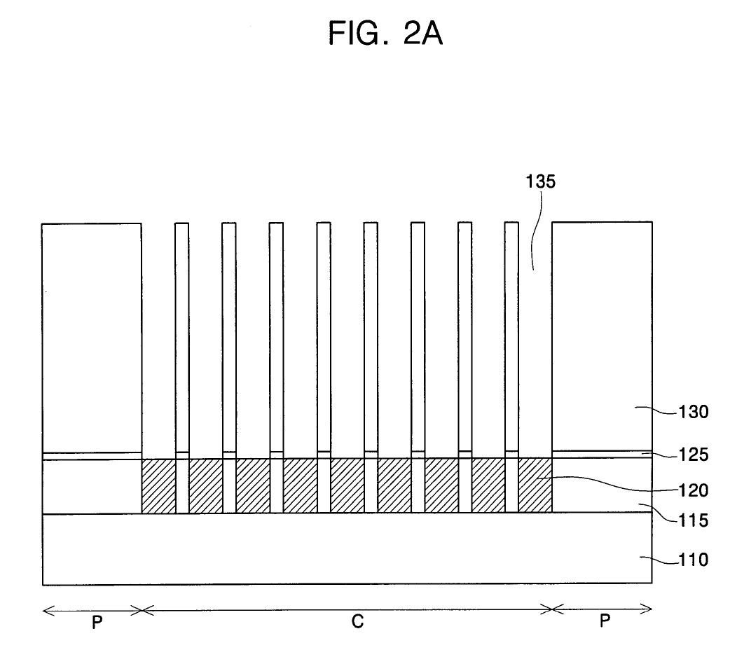

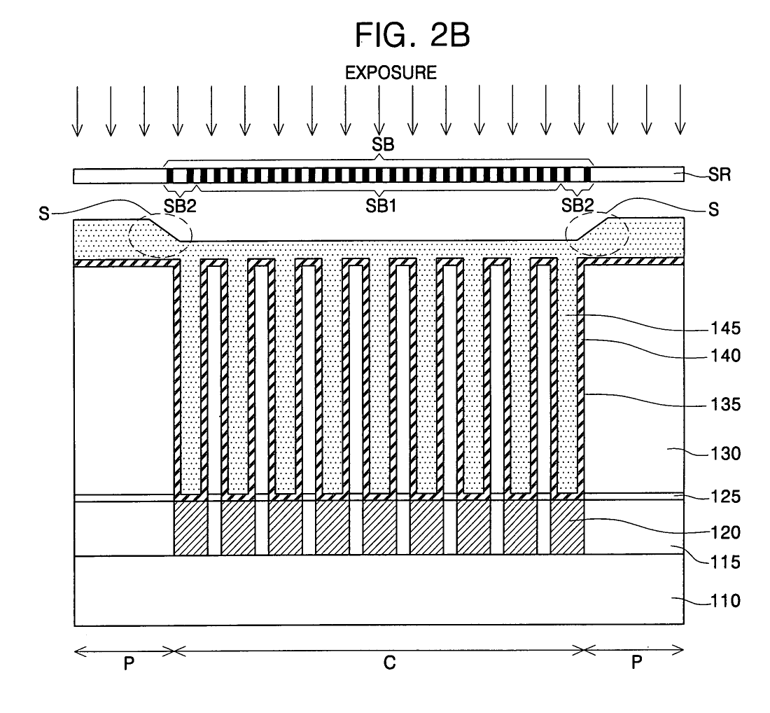

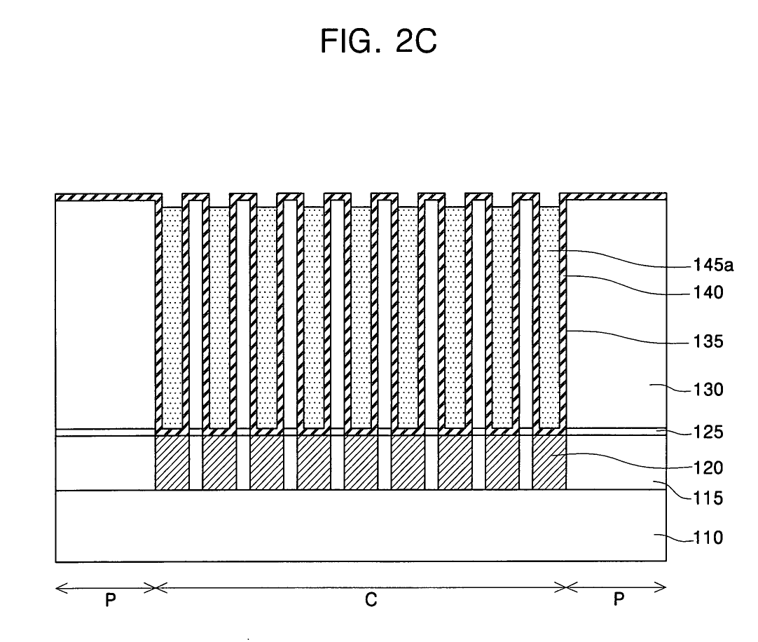

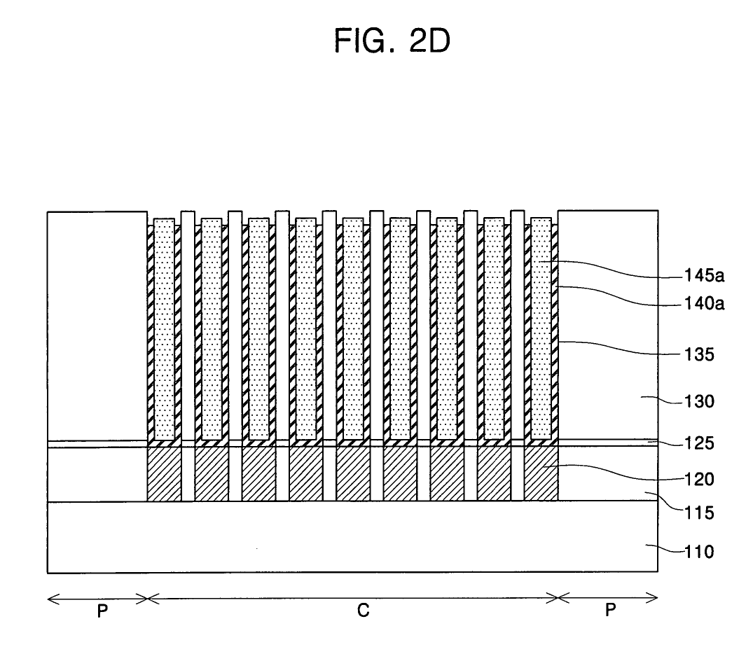

FIGS. 2A to 2D are sectional views illustrating a method of forming a storage node of a capacitor according to an embodiment of the present invention.

Referring to FIG. 2A, a cell region C and a peripheral circuit region P are defined in a semiconductor substrate 110. An interlayer insulating layer 115 is formed on the semiconductor substrate 110. The interlayer insulating layer 115 may be formed of an oxide layer, borophosphosilicate glass (BPSG), or phosphosilicate glass (PSG). Before the interlayer insulating layer 115 is formed, even though not shown in the drawing, transistors and a bit line are formed on the semiconductor substrate 110. The interlayer insulating layer 115 is patterned, thereby forming buried contact holes exposing predetermined portions of the semiconductor substrate 110. Buried contact plugs 120 are formed in the buried contact holes. The buried contact plugs 120 are formed to connect a lower structure, such as a transistor, and a subsequent storage node. In one embodiment, the buried contact plugs 120 are formed of polysilicon.

An etch stop layer 125 and a molding layer 130 are sequentially formed on the semiconductor substrate having the buried contact plugs 120. In one embodiment, the etch stop layer 125 is formed of a silicon nitride layer. The molding layer 130 may optionally be formed, for example, of an oxide layer, a BPSG layer, or a PSG layer. The molding layer 130 and the etch stop layer 125 are sequentially patterned, thereby forming storage node holes 135 exposing the buried contact plugs 120.

The semiconductor substrate having the storage node holes 135 is cleaned using a cleaning solution. A natural oxide layer and contaminants formed on the surfaces of the exposed buried contact plugs 120 are removed by the cleaning procedure. The cleaning solution normally employs a chemical solution including fluoric acid. Thus, the molding layer 130 exposed by the storage node holes 135 can also be isotropically etched by the cleaning solution. Thus, the widths of the storage node holes 135 can be widened.

Referring to FIG. 2B, a conformal storage node layer 140 is formed on the semiconductor substrate having the storage node holes 135. In order to increase a capacitance of a cell capacitor in the limited cell area, a dielectric layer during a subsequent process may use a high-k dielectric layer. Thus, in order to use the high-k dielectric layer, the storage node layer 140 may use a valuable metal material such as platinum (Pt), ruthenium (Ru), iridium (Ir), rhodium (Rh), osmium (Os), and the like having a very high work function, or a conductive compound such as TiN and the like. In this embodiment, the storage node layer 140 is formed of a TiN layer.

A photosensitive layer 145 with a sufficient thickness is formed on the semiconductor substrate having the storage node layer 140 in order to fully fill the storage node holes 135. At this time, since a photosensitive layer is drawn into the storage node holes 135 in the cell region C having the storage node holes 135 formed therein, a height of the photosensitive layer 145 in the cell region C may be lower than that in the peripheral circuit region P, thereby to cause a step height difference S in the structure.

An entire surface of the semiconductor substrate having the photosensitive layer 145 is exposed using a reticle SR having a scattering bar SB. At this time, an exposure energy is set under the conditions that the photosensitive layer 145 of the peripheral circuit region P is all removed after development. The scattering bar SB may be composed of a line and space pattern or an island pattern, or combination thereof.

The scattering bar SB is formed in the reticle SR to correspond with the cell region C. Thus, exposure energy passing the scattering bar SB of the reticle SR is reduced and thus, the exposure energy incident on the cell region C corresponding with the scattering bar SB is also reduced. At this time, by arranging a density of the scattering bar region SB2 opposite to the interface area of the peripheral circuit region P and the cell region C lower than that of a scattering bar SB1 opposite to the cell region C, the amount of exposure energy can be controlled in accordance with the inclined shape of a step height difference S of the photosensitive layer 145 between the cell C and peripheral P regions.

Referring to FIG. 2C, the exposed semiconductor substrate is developed. As a result, even though an exposure is performed under the condition that the photosensitive layer 145 in the peripheral circuit region P is entirely removed after development, since the photosensitive layer 145 of the cell region C is exposed by a relatively low exposure energy due to the scattering bar SB, the photosensitive layer 145 can be removed a reduced amount so that a thickness of the photosensitive layer as much as an exposed thickness of the storage node layer 140 on the molding layer 130 remains. Thus, the photosensitive layer 145a in the storage node holes 135 can remain to a higher level, as compared to the conventional approach.

Referring to FIG. 2D, an etch-back process is performed to separate storage nodes on the developed semiconductor substrate. As a result, the exposed portions of the storage node layer 140 are etched, thereby forming storage nodes 140a, upper portions of which are disconnected. Specifically, since the portion of the storage node layer 140 on the sidewalls of the storage node hole 135 is protected by the photosensitive layer 145a in the storage node holes 135, the storage nodes 140a are removed to an amount just below the level of the etch-back process and their lower portions are therefore maintained. Thus, since the area of the storage nodes 140a can be maximally retained, the resulting capacitance of capacitors to be formed using the storage nodes 140a can be increased in comparison with the conventional approach.

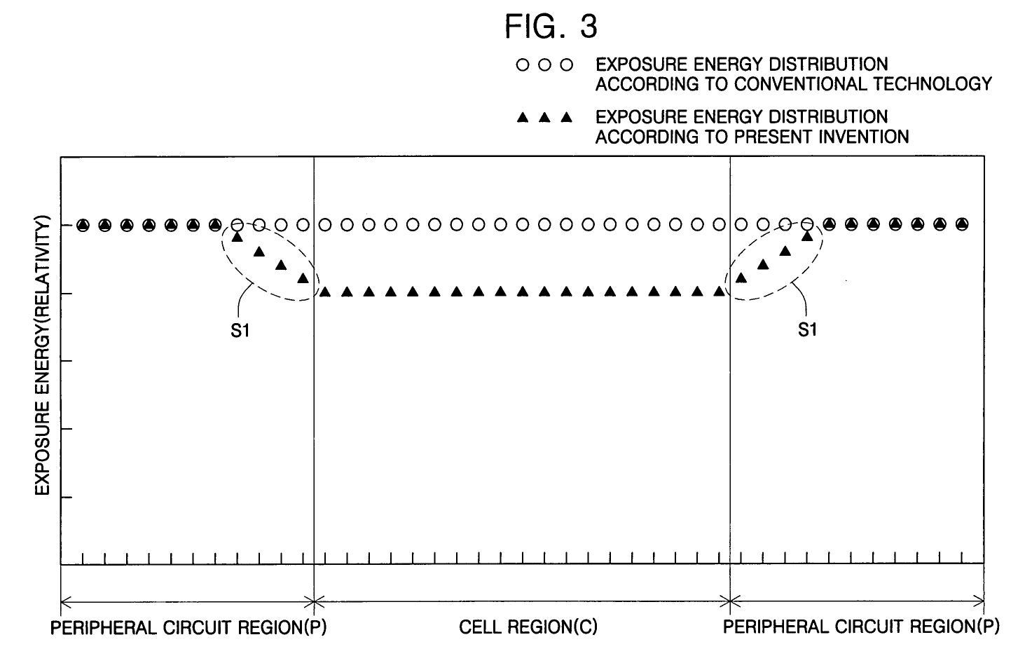

FIG. 3 is a graph illustrating comparison of exposure energy of a peripheral circuit region and a cell region according to a conventional technology and an embodiment of the present invention.

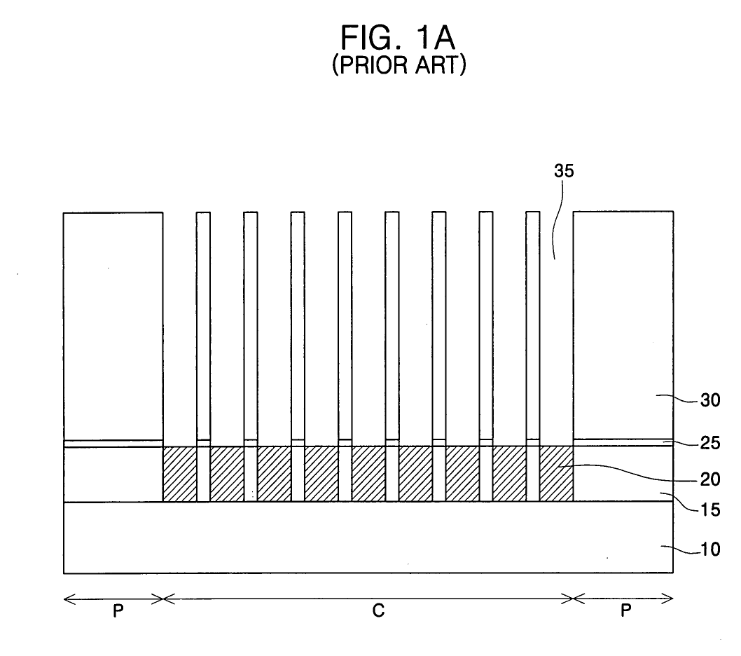

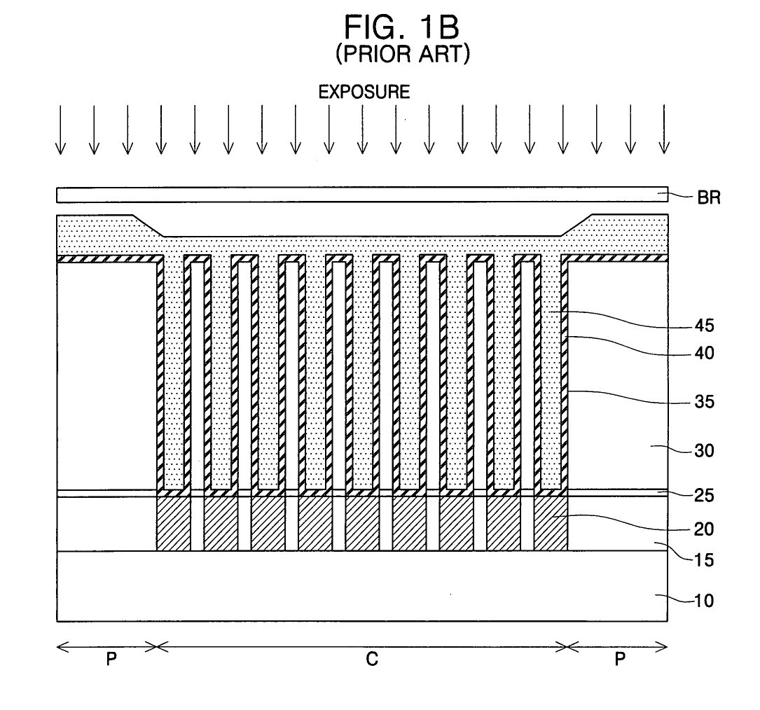

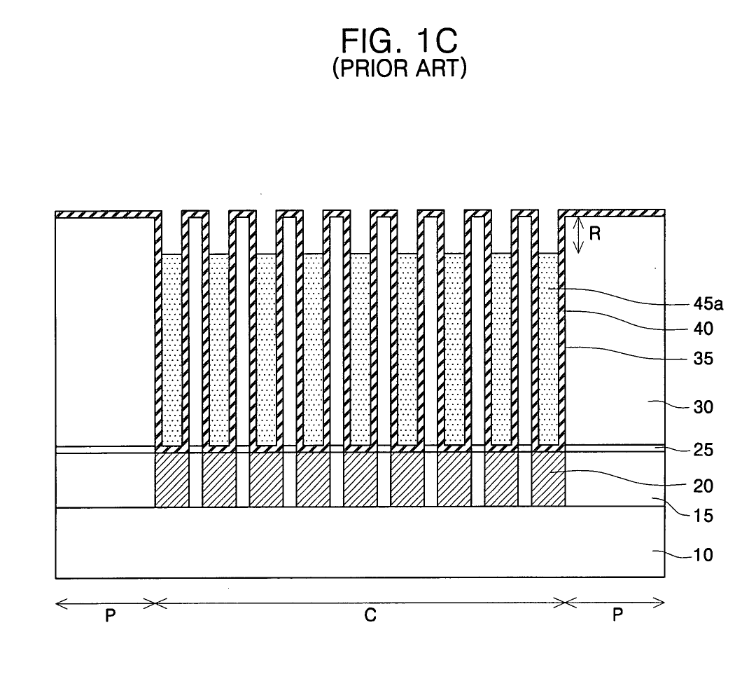

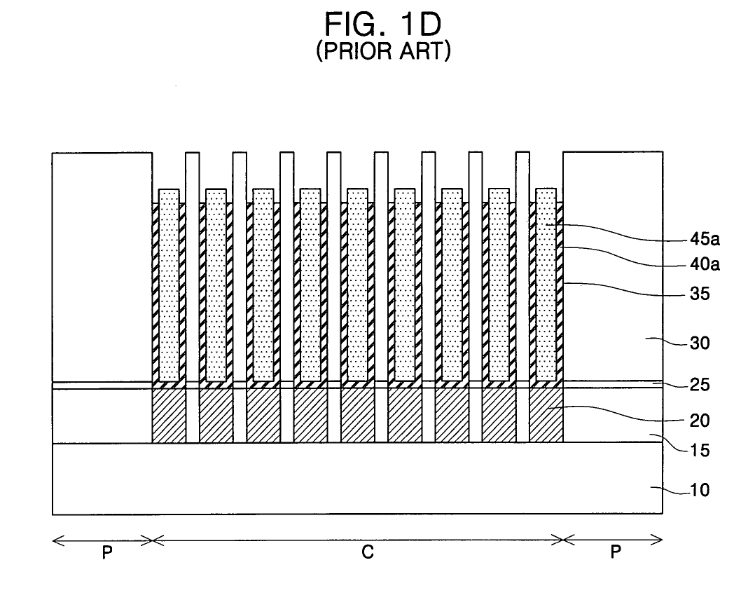

Referring to FIG. 3, when the semiconductor substrate having a deposited photosensitive layer is exposed, as shown in FIG. 1B of a conventional technology, using a blank reticle BR or without a reticle, exposure energy distributions (◯) in the peripheral circuit region P and the cell region C are shown. The exposure energy distributions (◯) according to a conventional technology show that an exposure energy is uniformly distributed among the peripheral circuit region P and the cell region C. As a result, since the photosensitive layer of the cell region C, which is relatively thin in thickness in comparison with the photosensitive layer of the peripheral circuit region P, is excessively exposed, the photosensitive layer in the storage node holes is partially recessed during the development process.

In the meantime, when the semiconductor substrate having a deposited photosensitive layer is exposed, as shown in FIG. 2B according to an embodiment of the present invention, using a reticle SR having a scattering bar SB, exposure energy distributions (▴) in the peripheral circuit region P and the cell region C are shown. An exposure energy in the cell region C corresponding to the scattering bar SB is reduced by the scattering bar SB. As a result, exposure energy distributions (▴) according to is the present invention show that exposure energies irradiated in the peripheral circuit region P and the cell region C are different. Thus, since the photosensitive layer in the cell region C receives a relatively low exposure energy by the scattering bar SB in a subsequent development process, the photosensitive layer in the storage node holes can be maintained.

The exposure energy distribution S1 having a slope at the interface area of the peripheral circuit region P and the cell region C shows that an amount of exposure energy is varied depending on the inclined step height shape S of the photosensitive layer. This lowers the density of the scattering bar SB2 corresponding to the interface in comparison with a density of the scattering bar SB1 corresponding to the cell region C, thereby allowing the amount of the exposure energy to be controlled.

As described above, in the process of separating storage nodes according to the present invention, a photosensitive layer is deposited and then, is exposed using a reticle having a scattering bar that is positioned to correspond with to the cell region during an exposure. Thus, irradiated exposure energy is different due to the thickness difference of the photosensitive layers in the peripheral circuit region and the cell region respectively. As a result, as excessive loss of the photosensitive layer in the cell region during a subsequent development process can be prevented, heights of the storage nodes can be maintained as high as possible during separation of the storage nodes by an etch-back process. Thus, the resulting area for the storage nodes can be maintained during the node separation procedure, and the capacitance of the resulting capacitors can be further increased in comparison with the conventional technology.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A method of forming a storage node of a capacitor comprising:
defining a cell region and a peripheral circuit region in a semiconductor substrate;
forming an interlayer insulating layer on the semiconductor substrate of the cell region and the peripheral circuit region;
forming buried contact plugs penetrating the interlayer insulating layer of the cell region;
forming a molding layer on the semiconductor substrate of the cell region and the peripheral circuit region;
patterning the molding layer of the cell region, thereby forming storage node holes exposing the buried contact plugs;
forming a conformal storage node layer on the semiconductor substrate having the storage node holes;
forming a photosensitive layer on the semiconductor substrate having the storage node layer, the photosensitive layer in the cell region being lower in height than the photosensitive layer in the peripheral circuit region;
exposing the semiconductor substrate using a reticle having a scattering bar, the scattering bar of the reticle being positioned to correspond with the cell region;
removing an exposed portion of the photosensitive layer by developing the semiconductor substrate, thereby partially exposing the storage node layer while maintaining the photosensitive layer in the storage node holes; and
performing an etch-back on the semiconductor substrate having the exposed storage node layer, thereby separating storage nodes.

2. The method according to claim 1, further comprising forming an etch stop layer between the interlayer insulating layer and the molding layer.

3. The method according to claim 1, wherein the storage node layer is formed of a metal layer or conductive compound.

4. The method according to claim 3, wherein the storage node layer is formed of a TiN layer.

5. The method according to claim 1, wherein the photosensitive layer is formed to fully fill the storage node hole.

6. The method according to claim 1, wherein in exposing the semiconductor substrate, an exposure energy passing through the scattering bar of the reticle is reduced so that an exposure energy of the cell region corresponding to the scattering bar is reduced.

7. The method according to claim 1, wherein the scattering bar is composed of a line and space pattern or an island pattern, or combination thereof.
